(19) United States
(12) Patent Application Publication
(10) Pub. No.: US 2026/0036634 A1
(43) Pub. Date: Feb. 5, 2026

(54) PHASE ERROR COMPENSATION IN BATTERY CELL VOLTAGE MEASUREMENT SYSTEMS

(71) Applicant: Renesas Electronics America Inc., Milpitas, CA (US)

(72) Inventor: Anthony John ALLEN, Campbell, CA (US)

(73) Assignee: Renesas Electronics America Inc., Milpitas, CA (US)

(21) Appl. No.: 18/788,668

(22) Filed: Jul. 30, 2024

(51) Int. Cl. G01R 31/3835; G01R 31/36; G01R 31/389

(52) U.S. Cl. CPC G01R 31/3835; G01R 31/3648; G01R 31/389

(57) ABSTRACT

Systems and methods for compensating phase errors in battery cell voltage measurement systems is generally described. The method can include identifying a plurality of time constants corresponding to a plurality of filter circuits connected to a plurality of battery cells. The method can further include determining, based on the plurality of time constants, a plurality of sampling times for the plurality of filter circuits. The method can further include sampling voltages from the plurality of battery cells according to the plurality of sampling times to compensate phase errors among the voltages being sampled from the plurality of battery cells.

### BACKGROUND

The present disclosure relates to systems and methods for compensating phase errors in battery cell voltage measurement systems.

Multi-cell batteries such as those used in electric vehicles or in fixed base energy storage systems can have circuits measuring the voltage and current of cells in the battery pack. The complex impedance of each of the cells in these battery packs can be determined based on the timing of the measured voltages and current. The measured impedance characteristics can be used for monitoring the health of the cells and for extracting various information of the cells, such as temperature information.

### SUMMARY

In one embodiment, a method for compensating phase errors in battery cell voltage measurement systems is generally described. The method can include identifying a plurality of time constants corresponding to a plurality of filter circuits connected to a plurality of battery cells. The method can further include determining, based on the plurality of time constants, a plurality of sampling times for the plurality of filter circuits. The method can further include sampling voltages from the plurality of battery cells according to the plurality of sampling times to compensate phase errors among the voltages being sampled from the plurality of battery cells.

In one embodiment, a semiconductor device for compensating phase errors in battery cell voltage measurement systems is generally described. The semiconductor device can include a controller configured to identify a plurality of time constants corresponding to a plurality of filter circuits connected to a plurality of battery cells. The controller can further be configured to determine, based on the plurality of time constants, a plurality of sampling times for the plurality of filter circuits. The semiconductor device can further include a circuit configured to sample voltages from the plurality of battery cells according to the plurality of sampling times to compensate phase errors among the voltages being sampled from the plurality of battery cells.

In one embodiment, a system for compensating phase errors in battery cell voltage measurement systems is generally described. The system can include at least one battery cell. The system can further include a controller configured to identify a plurality of time constants corresponding to a plurality of filter circuits connected to the at least one battery cell. The controller can further be configured to determine, based on the plurality of time constants, a plurality of sampling times for the plurality of filter circuits. The system can further include a circuit configured to sample voltages from the at least one battery cell according to the plurality of sampling times to compensate phase errors among the voltages being sampled from the at least one battery cell.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1A is a diagram showing an example system that can implement phase error compensation in battery cell voltage measurement systems in one embodiment.

FIG. 1B is a diagram showing another example system that can implement phase error compensation in battery cell voltage measurement systems in one embodiment.

FIG. 2 is a diagram showing another example system that can implement phase error compensation in battery cell voltage measurement systems in one embodiment.

FIG. 3 is a diagram showing another example system that can implement phase error compensation in battery cell voltage measurement systems in one embodiment.

FIG. 4 is a diagram showing another example system that can implement phase error compensation in battery cell voltage measurement systems in one embodiment.

FIG. 5 is a flow diagram illustrating a process to implement battery reactive impedance measurement in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

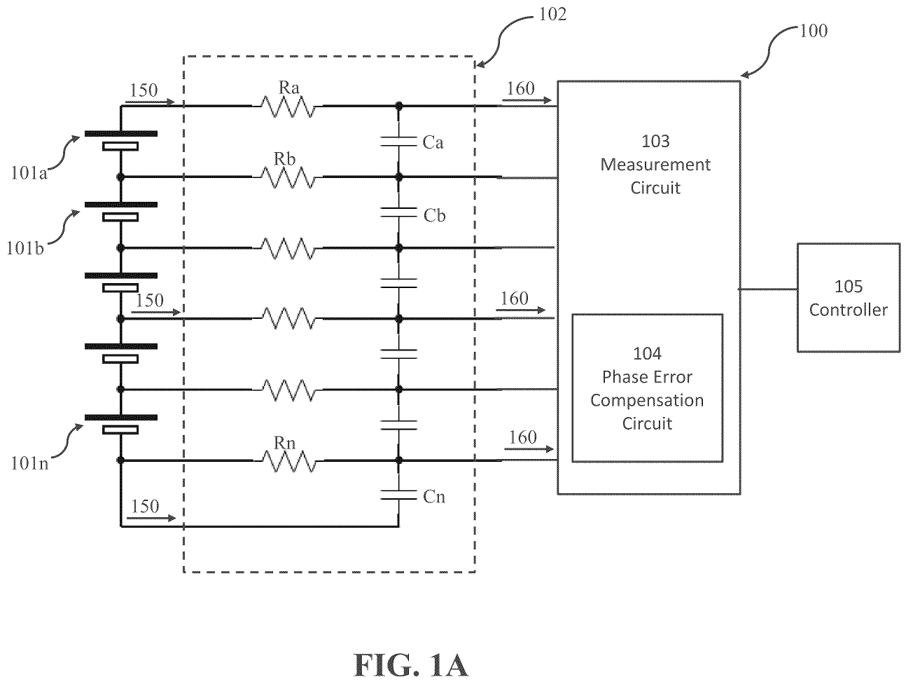

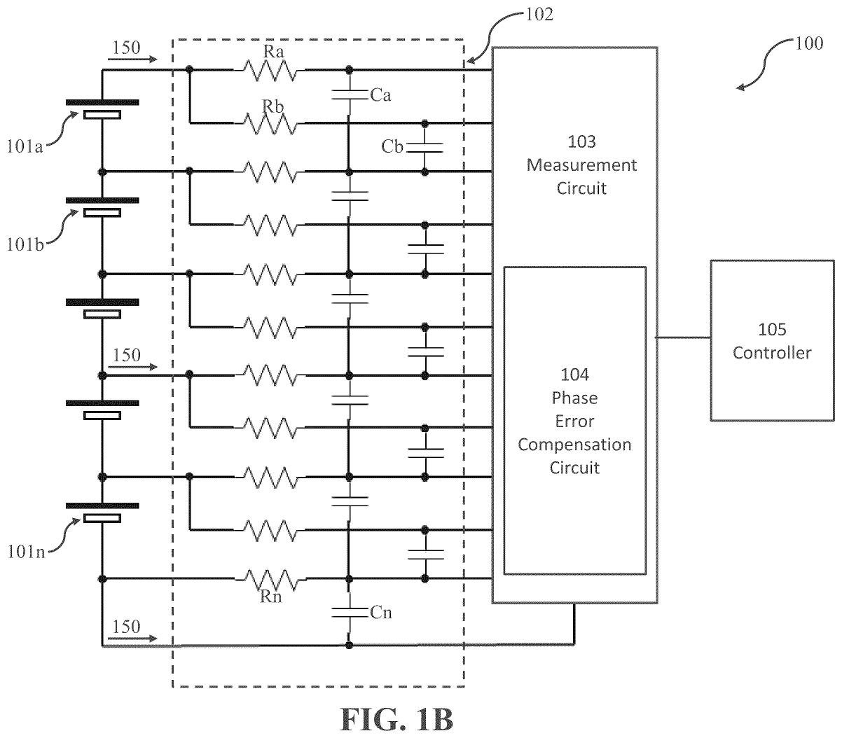

FIG. 1A is a diagram showing an example system that can implement phase error compensation in battery cell voltage measurement systems in one embodiment. System 100 can implement a battery pack using one or more semiconductor devices. System 100 can comprise of at least one battery cell, such as battery cells 101a, . . . 101n (collectively referred to as “cells 101” herein), an input filter circuit 102, a measurement circuit 103 and controller 105.

Each one of battery cells 101 can be, for example, an energy-storing unit, composed of an anode, a cathode, and an electrolyte, working together to generate power for a device or an electric/hybrid vehicle. A variety of battery cell types, each utilizing different elements, can be employed to construct a battery cell. For instance, Lithium-Ion batteries feature a lithium-based anode, while Nickel Manganese Cobalt (NMC) battery types incorporate an NMC cathode component. Input filter circuit 102 can comprise of at least one capacitor, such as capacitor Ca, Cb, . . . . Cn (collectively referred to as “capacitors C” herein) and at least one resistor, such as resistor Ra, Rb, . . . . Rn (collectively referred to as “resistor R” herein). The input filter circuit 102 can include a plurality of Resistor-Capacitor (RC) filters where each RC filter can comprise of a capacitor C connected in parallel to a corresponding battery cell of battery cells 101 and a resistor R connected in series to the corresponding battery cell of battery cells 101 and capacitor C. For example, capacitor Ca is connected in parallel to battery cells 101a, resistor Ra is connected in series to the battery cells 101a, capacitor Ca and the measurement circuit 103. In the example embodiment shown in FIG. 1A, each RC filter in input filter circuit 102 can be configured to receive voltage and/or current signals 150 (hereinafter “input signals 150”) from battery cells 101 and outputs filtered voltage and/or current signals 160 (hereinafter “filtered signals 160”) to measurement circuit 103.

Controller 105 can include one or more semiconductor devices that can implement, for example, a processor, microcontroller, central processing unit (CPU), field-programmable gate array (FPGA) or any other circuitry that is configured to control and operate system 100. While described as a CPU in illustrative embodiments, controller 105 is not limited to a CPU in these embodiments and may comprise any other circuitry that is configured to control and operate system 100. Controller 105 can be configured to communicate and control components such as measurement circuit 103.

Measurement circuit 103 can be configured to measure the voltage of a battery cells 101. Before being measured by the measurement circuit 103, the voltage and/or current signals 150 require filtering by input filter circuit 102. This filtering reduces noise and improves robustness against external interference. However, the components in input filter circuit 102 can induce significant phase differences between inputs, i.e., phase errors. These phase errors can lead to errors in the time alignment of signals measured by circuit 103. To be described in more detail below, measurement circuit 103 can comprise of a phase error compensation circuit 104. Phase error compensation circuit 104 can be configured to compensate these phase errors by controlling when to sample the filtered signals 160 based on time constants uploaded by controller 105.

FIG. 1B is a diagram showing another example system that can implement compensation of phase errors in one embodiment. In the example embodiment, each filter among input filter circuit 102 can comprise two capacitors C and two resistors R. Each filter can comprise of two capacitors C connected in parallel to a corresponding battery cell of battery cells 101. Each capacitor corresponding to a battery cell of battery cells 101 is connected in series to the corresponding capacitor. Also each filter shown in FIG. 1B includes two resistors Ra and Rb that are parallel to each other, and resistors Ra, Rb are connected in series with a corresponding batter cell. Capacitor Ca can be connected between resistors Ra, Rb and capacitor Cb can be connected between resistor Rb and a copy of resistor Ra connected to a next battery cell. Input filter circuit 102 can be configured with a least one capacitor C connected in parallel with each battery cells 101 and at least one resistor R connected in series to each battery cells 101 and to the capacitor C and measurement circuit 103.

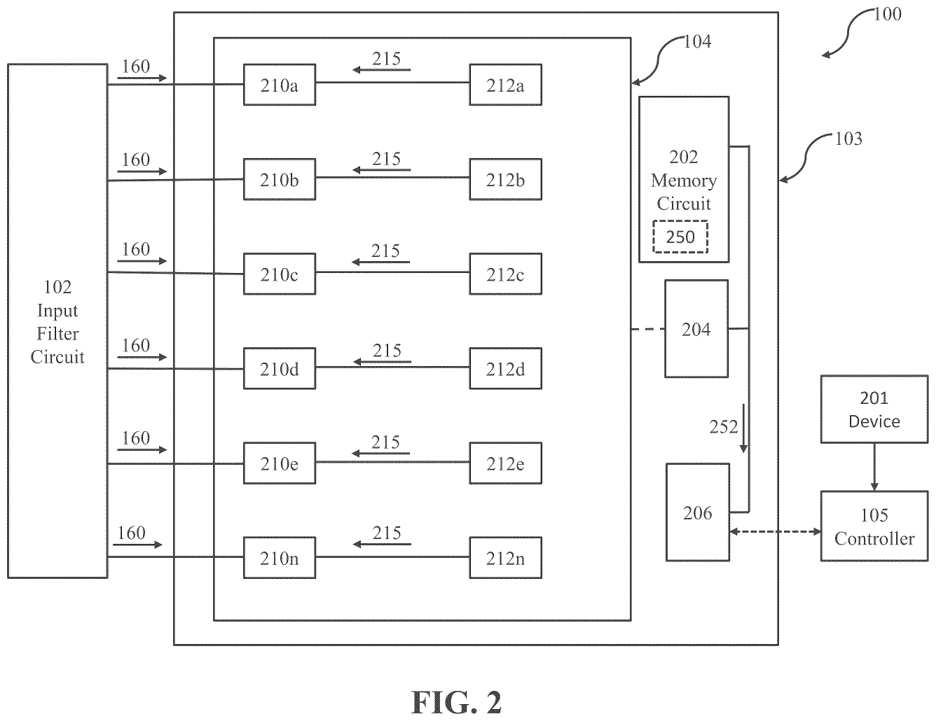

FIG. 2 is a diagram illustrating an implementation of compensation of phase errors in another embodiment. Descriptions of FIG. 2 may reference components shown in FIG. 1. In the example embodiment, measurement circuit 103 can further comprise of memory circuit 202, measurement control circuit 204, and communication interface 206. Memory circuit 202 can comprise of components configured to store data and/or instructions to be used by components such as controller 105 and phase error compensation circuit 104. Memory circuit 202 can include both volatile memory (e.g., RAM) and non-volatile memory (e.g., EEPROM). In one embodiment, memory circuit 202 can include a plurality of registers configured to store time constants 250 to be used by the measurement control circuit 204. Communication interface 206 can comprise of electronic components and circuits configured to communicate with other components in system 100 such as controller 105.

Time constants 250 can be time values, e.g. 10 microseconds, determined based on corresponding base times and timing ratios. A base time of an input filter can be predefined and stored in memory circuit 202, and can be dependent on the characteristics of the input filter circuit 102. These characteristics can be, for example, the resistance and capacitance values of the resistor and/or capacitor, or whether the filter is a first order filter or a higher order filter. In one embodiment, the characteristics can include phase relationships between inputs of different input circuits 102. The phase relationships can be dependent on the type of input filters in input filter circuit 102, and can be stored in, for example, memory circuit 202. The phase relationships between inputs of different input filter circuits 102 can be used to produce a set of timing ratios. In one embodiment, each one of the time constants 250 can be a product of a corresponding base time and a corresponding timing ratio (e.g., time constant=base time×timing ratio). Note that the base time and the set of time ratios can be different for different types of input filter.

In one embodiment, time constants 250 can be determined by a system integrator and/or a computing device 201 (“device 201”), and device 201 can send the determined time constants to controller 105 to be stored in memory circuit 202. Device 201 can be, for example, a computer such as desktop computer, laptop computer, tablet devices, or other types of computing devices that can be configured to determine time constants 250. Controller 105 can set time constants 250 needed to compensate the phase errors as register values in memory circuit 202 via communication interface 206. Controller 105 can upload the time constants stored in memory circuit 202 to measurement control circuit 204. In one embodiment, different time constants based on base time and timing ratios of different types of input filters can be stored in memory circuit 202. Controller 105 can be programmed to identify and upload the time constant that corresponds to the type of input filter being used in input filter circuit 102 of system 100.

As an example, system 100 can comprise of 8 battery cells 101 and an input filter circuit 102 arranged as illustrated in FIG. 1A. Based on the configuration of the input filter circuit 102, example base times (row: Base time) and an example set of time ratios are shown in Table 1 below (column: Base time Ratio). In Example 1, a base time value of 10 microseconds (us) is used. Cell 1 corresponds to a time ratio of 0.5 and thus the time constant 250 of cell 1 would be 5 microseconds. Cell 2 corresponds to a time ratio of 0.75 and thus the time constant 250 of cell 2 would be 7.5 microseconds. In Example 2, a base time value of 20 microseconds is used. Cell 1 corresponds to a time ratio of 0.5 and thus the time constant 250 of cell 1 would be 10 microseconds, cell 2 corresponds to a time ratio of 0.75 and thus the time constant 250 of cell 2 would be 15 microseconds, etc.

TABLE 1

| | Base time Ratio | Example 1 | Example 2 |
|---|---|---|---|
| Base time (us) | | 10 | 20 |
| Cell 1 delay (us) | 0.5 | 5 | 10 |
| Cell 2 delay (us) | 0.75 | 7.5 | 15 |
| Cell 3 delay (us) | 1 | 10 | 20 |
| Cell 4 delay (us) | 1 | 10 | 20 |
| Cell 5 delay (us) | 1 | 10 | 20 |
| Cell 6 delay (us) | 1 | 10 | 20 |
| Cell 7 delay (us) | 0.75 | 7.5 | 15 |
| Cell 8 delay (us) | 0.5 | 5 | 10 |

Measurement control circuit 204 can comprise of logic function circuits configured to control functions in phase error compensation circuit 104, based on the time constants 250 stored in memory circuit 202. In addition, measurement control circuit 204 can read back the resulting conversion data 252 from phase error compensation circuit 104.

The phase error compensation circuit 104 of measurement circuit 103 can further comprise of a plurality of sampling circuits 210a, 210b, . . . 210n (collectively referred to as “sampling circuits 210” herein). Sampling circuits can comprise of various circuits configured to sample, hold, convert, or differentiate the filtered signals 160. Each one of sampling circuits 210 is configured to sample filtered signals 160 from a corresponding battery cell of battery cells 101 after being filtered by input filter circuit 102. Phase error compensation circuit 104 can further include time control circuits 212a, 212b, . . . 212n (collectively referred to as “time control circuits 212” herein). Each time control circuit of the time control circuits 212 is configured to generate timing signals 215 based on the time constants 250 received from measurement control circuit 204. Time control circuits 212 generate timing signals 215 that trigger the sampling circuits 210 to sample filtered signals 160 at a specified time.

In an aspect, if all sampling circuits 210 sample their respective filtered signals 160 at the same time, the captured instantaneous voltage of each filtered signal 160 may contain phase variations. To reduce or eliminate phase variations, measurement control circuit 204 can receive the time constants 250 stored in memory circuit 202 and provide the time constants 250 to time control circuits 212. Time control circuits 212 can generate their respective timing signals 215 using time constants 250. In one embodiment, each one of time control circuits 212 can receive an individual time constant among time constants 250 from measurement control circuit 204.

Measurement control circuit 204 can control each time control circuit of time control circuits 212 individually by identifying and distributing the appropriate time constant among time constants 250 to time control circuits 212. Each time control circuit of time control circuits 212 can generate a timing signal 215 with a specified delay represented by a time constant 250 received from measurement control circuit 204. By way of example, a time constant 250 being provided to time control circuit 212a can be 10 microseconds and sampling circuit 210a can be programmed to a default sampling time of X.

Time control circuit 212a can generate a timing signal 215 encoding the time constant 250 of 10 microseconds and provide the timing signal 215 to sampling circuit 210a. Sampling circuit 210a can receive the timing signal 215 encoding 10 microseconds, sample its filtered signal 160 at the default sampling time X with an additional delay of 10 microseconds, i.e., sample at X+10 microseconds). Sampling circuit 210 can also be configured to hold the sampled filtered signal 160 until a predefined release time (e.g., 5 microseconds). Sampling circuit 210 can also be configured to determine that the predefined release time has lapsed, then provide the sampled voltages to the measurement control circuit 204 after the lapse of the predefined release time.

Time control circuit 212b can generate a timing signal 215 encoding the time constant 250 of 15 microseconds and provide the timing signal 215 to sampling circuit 210b. Sampling circuit 210b can receive the timing signal 215 encoding 15 microseconds, sample its filtered signal 160 at the default sampling time X with and additional delay of 15 microseconds, i.e., sample at X+15 microseconds. By delaying sample circuits 210 with individually different time constants can synchronize sampling across all filtered signals 160, thereby aligning their phases, removing phase differences, and facilitating phase error compensation.

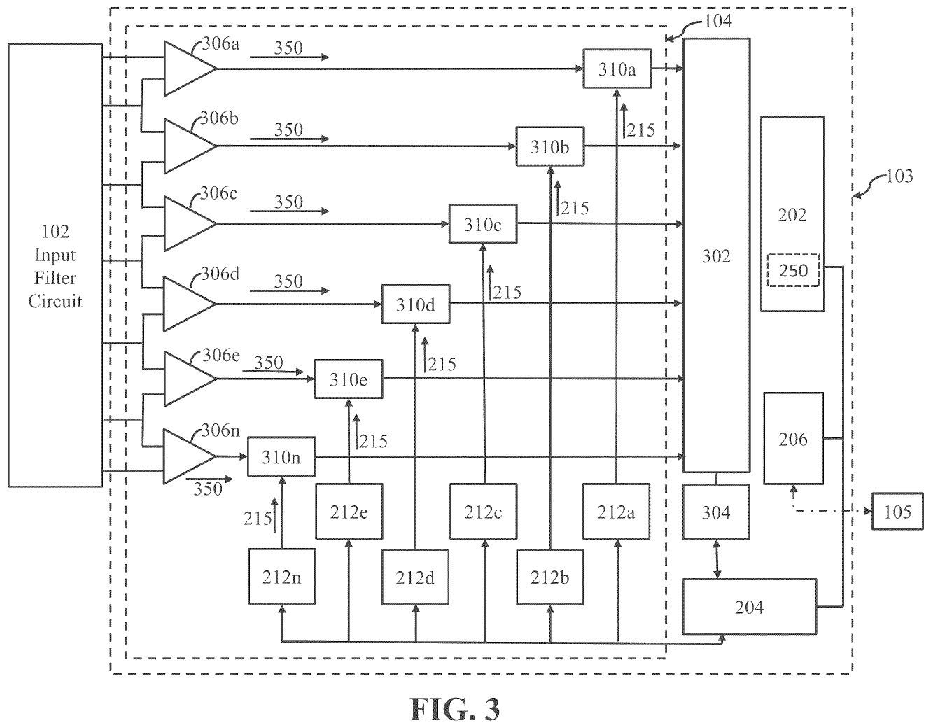

FIG. 3 is a diagram illustrating an implementation of compensation of phase errors in another embodiment. Descriptions of FIG. 3 may reference components shown in FIG. 1 and FIG. 2. In the example embodiment, sampling circuits 210 can comprise of differential operational amplifiers 306a, 306b, . . . 306n (collectively referred to as “operational amplifiers 306” herein). Sample circuits 212 can further comprise of a sample-and-hold (S/H) circuits 310a, 310b, . . . 310n (collectively referred to as “S/H circuits 310” herein). The operational amplifiers 306 can be configured to receive the filtered signals 160 outputted from input filter circuit 102. Each operational amplifier 306 can be configured to receive the filtered signals 160 from two adjacent battery cells and amplify the differential voltage between them. For example, operational amplifier 306a may receive the filtered signals from battery cells 101a and 101b, operational amplifier 306b may receive the filtered signals from battery cells 101b and 101c, and so on. By amplifying the differential signal between adjacent cells, the operational amplifiers 306 can generate a voltage signals 350 representing the voltage in each individual cell in the battery pack.

The output of each operational amplifier 306 can then be received by the corresponding S/H circuit of S/H circuits 310. S/H circuits 310 can be configured to capture the instantaneous value of the voltage signals 350 after a specific delayed duration defined by the corresponding time constant of time constants 250. If all S/H circuits 310 samples the voltage signals 350 at the exact same time, the phase errors created by the input filter circuit 102 can create errors in the measurements. By using measurement control circuit 204 to control the timing of the sampling circuit 210, the sampling times can be individually controlled to compensate for the phase errors caused by the input filter circuit 102.

The measurement circuit 103 illustrated in FIG. 3 can further comprise of a multiplexer (MUX) 302 and an analog-to-digital converter (ADC) 304. The MUX 302 is configured to select one of a plurality of sampled voltage signals 350 output from every sampling circuit 210 and route it to a single output, which is connected to the input of the ADC 304. The ADC 304 can be configured to convert the sampled voltage signals 350 received from the MUX 302 into a digital representation that can be processed by controller 105. The ADC 304 has a specific resolution (e.g., 12-bit, 16-bit) that determines the number of discrete digital values it can produce over the input voltage range.

The MUX 302 receives the sampled voltage signals 350 from the sampling circuits 210. Controller 105 can be configured to control MUX 302 to sequentially select each of the sampled voltage signals 350 and forwards them, one at a time, to the ADC 304 for digitization. ADC 304 is configured to sample the signal 350 at a specific sampling rate after a specified delay in time defined by the corresponding time constant of time constants 250 and converts the sampled values into discrete digital codes encoding the sampled voltage signals 350. The digital output of the ADC 304 is then sent to a microcontroller or other digital system, such as controller 105, for further processing, such as voltage monitoring and/or determine reactive impedance of battery cells 101.

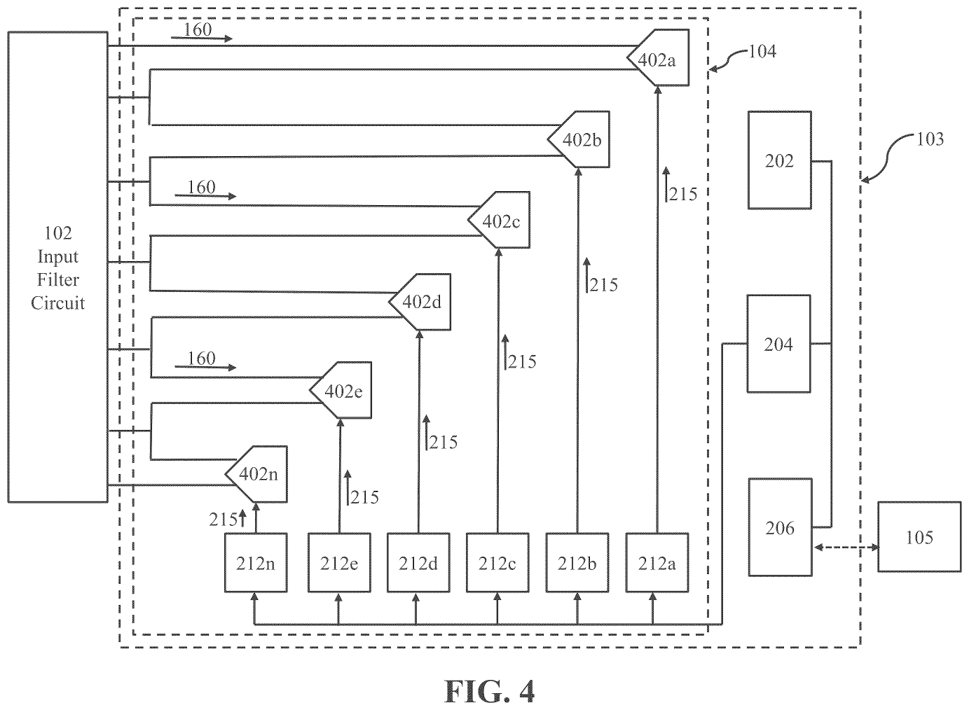

FIG. 4 is a diagram illustrating another implementation of compensation of phase errors in another embodiment. Descriptions of FIG. 4 may reference components shown in FIG. 1 and FIG. 3. In the example embodiment, sampling circuits 210 can comprise of plurality of ADCs 402a, 402b, . . . 402n (collectively referred to as “ADCs 402” herein). Each ADC of the plurality of ADCs 402 is associated with a specific pair of input voltage signals and is configured to measure the differential voltage between them. The filtered signals 160 from two adjacent battery cells are directly connected to the inputs of a corresponding ADC of the plurality of ADCs 402.

Timing signals 215 can specify a sampling time for the corresponding ADC of the plurality of ADCs 402 to capture the filtered signals 160. Once the filtered signals 160 is sampled and held, the ADC 402 proceeds with the analog-to-digital conversion process. It converts the sampled voltage value into a discrete digital code based on its resolution (e.g., 12-bit, 16-bit). The digital output of the ADC 402 represents or encodes the differential voltage measurement between the two battery cells at the specific sampling instant. The digital output can then be sent to controller 105 to be used, e.g., to monitor system 100 and battery cells 101, or to determine reactive impedance of battery cells 101.

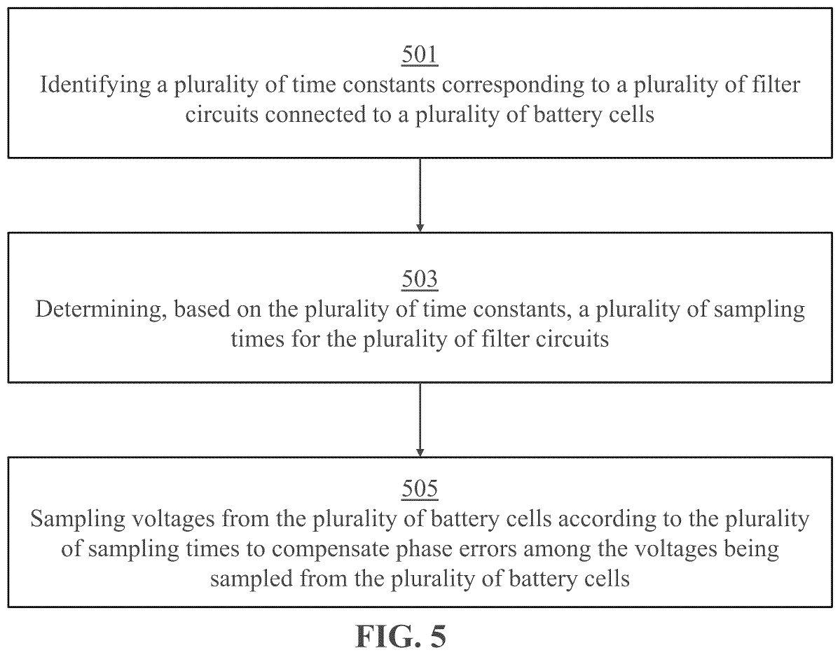

FIG. 5 is a flow diagram illustrating a process to implement battery reactive impedance measurement in one embodiment. A process 500 can include one or more operations, actions, or functions as illustrated by one or more of blocks 501, 503, and/or 505. Although illustrated as discrete blocks, various blocks can be divided into additional blocks, combined into fewer blocks, eliminated, performed in different order, or performed in parallel, depending on the desired implementation.

Process 500 can be performed by a system, such as a battery voltage measurement system (system 100 described herein). Process 500 can begin at block 501, where the system can identify a plurality of time constants corresponding to a plurality of filter circuits connected to a plurality of battery cells. The process 500 can continue from block 501 to block 503. At block 503, the system can determine, based on the plurality of time constants, a plurality of sampling times for the plurality of filter circuits. The process 500 can continue from block 503 to block 505. At block 505, the system can sample voltages from the plurality of battery cells according to the plurality of sampling times to compensate phase errors among the voltages being sampled from the plurality of battery cells.

In one embodiment, the plurality of time constants can be based on at least one characteristics that comprises at least one or more of resistance values of the plurality of filter circuits, capacitance values of the plurality of filter circuits, and a predefined base time value. In one embodiment, the system can further store the plurality of time constants in a memory circuit.

In one embodiment, the system determining the plurality of sampling times further includes, for a specific filter circuit among the plurality of filter circuits, determining a delay based on a specific time constant among the plurality of time constants. The specific time constant can correspond to the specific filter circuit. The system determining the plurality of sampling times further includes adding the delay to a default sampling time of the specific filter circuit to determine a specific sampling time of the specific filter circuit. The specific sampling time can be among the plurality of sampling times.

In one embodiment, the system can further hold the sampled voltages until a predefined release time. The system can further determine the predefined release time has lapsed. The system can further provide the sampled voltages to a measurement circuit after the lapse of the predefined release time. In one embodiment, the system can further convert, sequentially, the sampled voltages into digital signals encoding the sampled voltages. The system can further provide the digital signals to a measurement circuit. The measurement of a reactive impedance of the plurality of battery cells can be based on the digital signals.

In one embodiment, the system can further sample voltages from the plurality of battery cells comprises operating a plurality of analog-to-digital converters (ADCs) to convert the voltages from the plurality of battery cells into digital signals. The system can further provide the digital signals to a measurement circuit. The measurement of a reactive impedance of the plurality of battery cells can be based on the digital signals.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
identifying a plurality of time constants corresponding to a plurality of filter circuits connected to a plurality of battery cells;
determining, based on the plurality of time constants, a plurality of sampling times for the plurality of filter circuits; and
sampling voltages from the plurality of battery cells according to the plurality of sampling times to compensate phase errors among the voltages being sampled from the plurality of battery cells.

2. The method of claim 1, wherein the plurality of time constants are based on at least one characteristics that comprises at least one or more of:
resistance values of the plurality of filter circuits;
capacitance values of the plurality of filter circuits; and
a predefined base time value.

3. The method of claim 1, further comprising storing the plurality of time constants in a memory circuit.

4. The method of claim 1, wherein determining the plurality of sampling times comprises, for a specific filter circuit among the plurality of filter circuits:
determining a delay based on a specific time constant among the plurality of time constants, wherein the specific time constant corresponds to the specific filter circuit; and
adding the delay to a default sampling time of the specific filter circuit to determine a specific sampling time of the specific filter circuit, wherein the specific sampling time is among the plurality of sampling times.

5. The method of claim 1, further comprising:
holding the sampled voltages until a predefined release time;
determining the predefined release time has lapsed; and
providing the sampled voltages to a measurement circuit after the lapse of the predefined release time.

6. The method of claim 1, further comprising:
converting, sequentially, the sampled voltages into digital signals encoding the sampled voltages; and
providing the digital signals to a measurement circuit, wherein measurement of a reactive impedance of the plurality of battery cells is based on the digital signals.

7. The method of claim 1, wherein:
sampling voltages from the plurality of battery cells comprises operating a plurality of analog-to-digital converters (ADCs) to convert the voltages from the plurality of battery cells into digital signals; and
the method further comprising providing the digital signals to a measurement circuit, wherein measurement of a reactive impedance of the plurality of battery cells is based on the digital signals.

8. A semiconductor device comprising:
a controller configured to:
identify a plurality of time constants corresponding to a plurality of filter circuits connected to a plurality of battery cells;
determine, based on the plurality of time constants, a plurality of sampling times for the plurality of filter circuits; and
a circuit configured to:
sample voltages from the plurality of battery cells according to the plurality of sampling times to compensate phase errors among the voltages being sampled from the plurality of battery cells.

9. The semiconductor device of claim 8, wherein the plurality of time constants are based on at least one characteristics that comprises at least one or more of:
resistance values of the plurality of filter circuits;
capacitance values of the plurality of filter circuits; and
a predefined base time value.

10. The semiconductor device of claim 8, further comprising
a memory circuit configured to:
store the plurality of time constants.

11. The semiconductor device of claim 8, wherein the controller is further configured to, for a specific filter circuit among the plurality of filter circuits:
determine a delay based on a specific time constant among the plurality of time constants, wherein the specific time constant corresponds to the specific filter circuit; and
add the delay to a default sampling time of the specific filter circuit to determine a specific sampling time of the specific filter circuit, wherein the specific sampling time is among the plurality of sampling times.

12. The semiconductor device of claim 8, wherein the circuit is further configured to:
hold the sampled voltages until a predefined release time;
determine the predefined release time has lapsed; and
provide the sampled voltages to the controller after the lapse of the predefined release time.

13. The semiconductor device of claim 8, wherein the circuit is further configured to:
convert, sequentially, the sampled voltages into digital signals encoding the sampled voltages; and
provide the digital signals to a measurement circuit, wherein measurement of a reactive impedance of the plurality of battery cells is based on the digital signals.

14. The semiconductor device of claim 8, wherein the circuit is further configured to:
sample voltages from the plurality of battery cells comprises operating a plurality of analog-to-digital converters (ADCs) to convert the voltages from the plurality of battery cells into digital signals; and
provide the digital signals to a measurement circuit, wherein measurement of a reactive impedance of the plurality of battery cells is based on the digital signals.

15. A system comprising:
at least one battery cell;
a controller configured to:
identify a plurality of time constants corresponding to a plurality of filter circuits connected to the at least one battery cell;
determine, based on the plurality of time constants, a plurality of sampling times for the plurality of filter circuits; and
a circuit configured to:
sample voltages from the at least one battery cell according to the plurality of sampling times to compensate phase errors among the voltages being sampled from the at least one battery cell.

16. The system of claim 15, wherein the plurality of time constants are based on at least one characteristics that comprises at least one or more of:
resistance values of the plurality of filter circuits;
capacitance values of the plurality of filter circuits; and
a predefined base time value.

17. The system of claim 15, further comprising
a memory circuit configured to:
store the plurality of time constants.

18. The system of claim 15, wherein determining the plurality of sampling times comprises, for a specific filter circuit among the plurality of filter circuits:
determining a delay based on a specific time constant among the plurality of time constants, wherein the specific time constant corresponds to the specific filter circuit; and
adding the delay to a default sampling time of the specific filter circuit to determine a specific sampling time of the specific filter circuit, wherein the specific sampling time is among the plurality of sampling times.

19. The system of claim 15, wherein the circuit is further configured to:
hold the sampled voltages until a predefined release time;
determine the predefined release time has lapsed; and
provide the sampled voltages to the controller after the lapse of the predefined release time.

20. The system of claim 15, wherein the circuit is further configured to:
convert, sequentially, the sampled voltages into digital signals encoding the sampled voltages; and
provide the digital signals to a measurement circuit, wherein measurement of a reactive impedance of the at least one battery cell is based on the digital signals.
